(19) United States
(12) Patent Application Publication
(10) Pub. No.: US 2003/0168012 A1
(43) Pub. Date: Sep. 11, 2003

(54) Plasma processing device and plasma processing method

(76) Inventors: Hitoshi Tamura, Yamaguchi (JP); Seiichi Watanabe, Yamaguchi (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/218,413

(22) Filed: Aug. 15, 2002

(30) Foreign Application Priority Data
Mar. 7, 2002 (JP) 2002-061329

(51) Int. Cl. C23F 1/00; C23C 16/00

(52) U.S. Cl. 118/723 AN; 156/345.48

(57) ABSTRACT

The present invention creates a uniform high-density plasma within the plasma processing device, solving the problem of electric field concentration around the center axis of the device. The present invention comprises antennas (0113, 0114) having plural phase-controlled power feed points, which are used to introduce plasma-generating electromagnetic waves into a plasma processing chamber by a mode that does not cause electric field concentration at the center area.

### FIELD OF THE INVENTION

The present invention relates to a plasma processing device and plasma processing method for providing uniform plasma treatment to a wafer having a diameter of approximately 200 mm to 300 mm or more.

### DESCRIPTION OF THE RELATED ART

A conventional etching device is disclosed in Japanese Patent Laid-Open Application No. 11-260594. According to this disclosure, a uniform plasma distribution is realized by adjusting the field distribution within a processing chamber using a disk antenna with slot antennas provided thereto. The disk antenna is designed to introduce electromagnetic waves into the plasma processing chamber through a dielectric window.

According to the prior art, the electromagnetic waves introduced to generate plasma creates an electric field that is concentrated around the center of the chamber, and according to processing conditions, the uniformity of plasma density distribution is deteriorated.

### SUMMARY OF THE INVENTION

The above-mentioned prior art problem can be solved by introducing high frequency electromagnetic waves into the processing chamber in such a mode that the electric field is not concentrated around the center of the chamber. According to the conventional technique mentioned above, modes such as TM01, TM02 and TM03 using a circular waveguide is excited in the dielectric window, and these modes are considered to be the main modes for creating plasma. These modes comprise electric fields oriented along the axis of the waveguide around the center area of the chamber which cause the concentration of electric field at the center area. On the other hand, modes such as TM21, TM31 and TM41 include no electric field created along the center axis of the waveguide, so they do not cause electric field to concentrate around the center axis area. Furthermore, modes such as TM11 do not have electric field components oriented along the waveguide axis direction at the center area, so they too do not cause such problem. Therefore, the above-mentioned prior art problem can be solved by adopting these modes.

Modes such as TM21, TM31 and TM41 of a circular waveguide do not have electric fields disposed on the center axis of the circular waveguide, and thus in principle no electric field concentration at the center occurs. Further, modes such as TM11 do not have electric field components oriented in the waveguide axis direction on the center axis. Therefore, no specific phenomenon occurs along the center axis of the device, and thus a highly uniform plasma can be generated.

### BRIEF DESCRIPTION OF THE DRAWINGS

FIG. 1 is a cross-sectional view showing the etching device utilizing the present invention;

FIG. 2 is a cross-sectional view of the phase adjustment unit;

FIG. 3 is a cross-sectional view of the phase adjustment unit;

FIG. 4 is a cross-sectional view of the phase adjustment waveguide;

FIG. 5 is a graph illustrating the guide wavelength of the phase adjustment waveguide;

FIG. 6 illustrates the electric field distribution based on TM11 mode within the circular waveguide;

FIG. 7 illustrates a high frequency electric field distribution excited by the etching device utilizing the present invention;

FIG. 8 illustrates possible antenna structures;

FIG. 9 is a cross-sectional view illustrating the etching device utilizing the present invention;

FIG. 10 is a cross-sectional view illustrating the etching device utilizing the present invention;

FIG. 11 is a cross-sectional view illustrating the etching device utilizing the present invention;

FIG. 12 is a detailed cross-sectional view illustrating the antenna portion;

FIG. 13 is a detailed cross-sectional view illustrating the antenna portion;

FIG. 14 is a cross-sectional view showing the etching device utilizing the present invention;

FIG. 15 is a circuit diagram explaining the phase control utilizing the passive electric circuit elements;

FIG. 16 is a cross-sectional view illustrating the etching device utilizing the present invention;

FIG. 17 is an explanatory view showing the structure of the phase adjustment circuit;

FIG. 18 is a frame format view illustrating the electric field distribution; and

FIG. 19 illustrates possible antenna structures.

### DETAILED DESCRIPTION OF THE PREFERRED EMBODIMENT

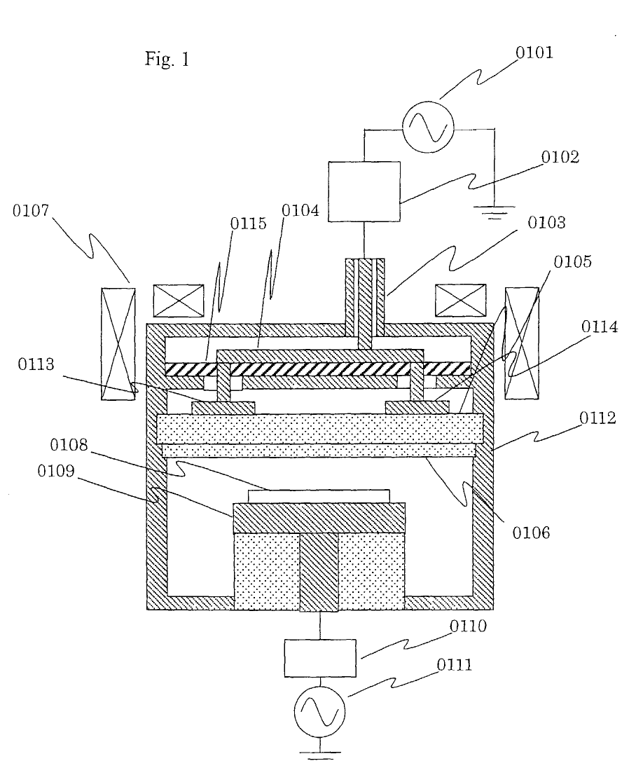

One preferred embodiment of the present invention will now be explained with reference to FIGS. 1 through 4. FIG. 1 illustrates an etching equipment adopting the present invention. Electromagnetic waves generated by a high frequency power supply 0101 having a frequency of 450 MHz are transmitted via an automatic matching device 0102 through a coaxial line 0103 to a phase adjustment circuit 0104. The phase adjustment circuit 0104 is connected to disk-shaped antennas 0113 and 0114, which radiate electromagnetic waves into a processing chamber 0112 through a dielectric window 0105 and a shower plate 0106. The radiated electromagnetic waves create plasma within the processing chamber 0112. Within the chamber 0112 is provided a substrate electrode 0109 onto which a wafer 0108 to be treated is mounted, the substrate electrode 0109 being connected to a high-frequency bias power source 0111 through a matching device 0110. By applying bias potential to the wafer 0108 through the high-frequency bias power source 0111 and drawing in the ions within the plasma to the wafer 0108, the speed of the etching treatment can be increased or the shape of the etching can be controlled. A vacuum discharge system and a gas introduction system not shown are connected to the processing chamber 0112 so as to maintain the inside of the processing chamber to a pressure and atmosphere suited for etching. Gas is introduced from a gap provided between the shower plate 0106 and dielectric window 0105 and through plural gas introduction holes provided to the shower plate 0106 into the processing chamber 0112. The dielectric window and the shower plate are made of material that provides minimum loss to electromagnetic waves and does not influence plasma treatment, such as quartz or alumina ceramic. The present embodiment utilizes quarts as material for forming the dielectric window and shower plate. Though according to the present embodiment a high frequency bias power source provides bias potential to the wafer upon performing etching treatment, but the present invention is not limited to such embodiment. In other words, in a CVD device and the like, there is no need to provide bias potential to the wafer using a bias power source.

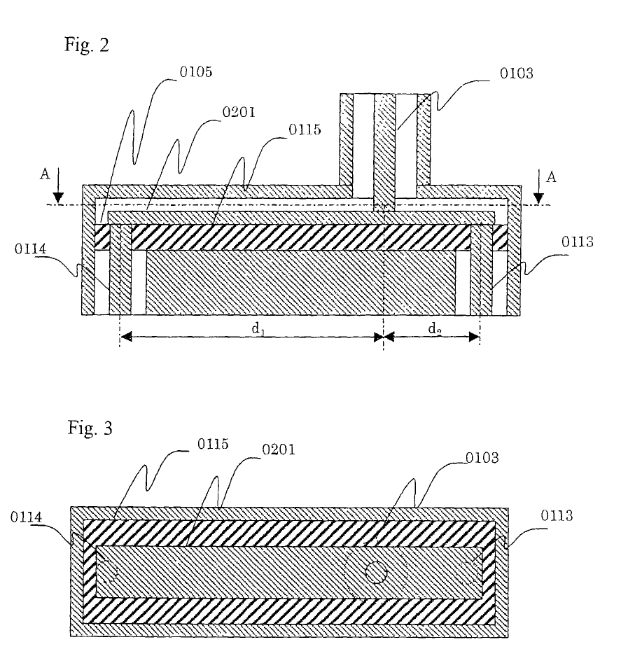

The details of the structure around the phase adjustment circuit 0104 are illustrated in FIGS. 2 and 3. FIG. 2 is an enlarged drawing of FIG. 1, and FIG. 3 is a cross-sectional view taken at line AA of FIG. 2. The coaxial line 0103 is connected to a metal plate 0201. The metal plate 0201 is disposed on a dielectric body 0115, for branching and transmitting the 450 MHz electromagnetic waves to the antennas 0113 and 0114. The antennas 0113 and 0114 each constitute an inner conductor of the coaxial line. The distance dl of the inner conductor between antenna 0114 and coaxial line 0103 and the distance d2 of the inner conductor between the antenna 0113 and coaxial line 0103 are set so that the difference in the distances corresponds to a half wavelength of the 450 MHz electromagnetic wave traveling through the metal plate 0201. Accordingly, after the electromagnetic waves traveling through the coaxial line 0103 are branched, they reach and excite the antennas 0113 and 0114 with a half-wavelength difference in the paths. Therefore, the antennas are excited with a mutual phase difference of 180 degrees.

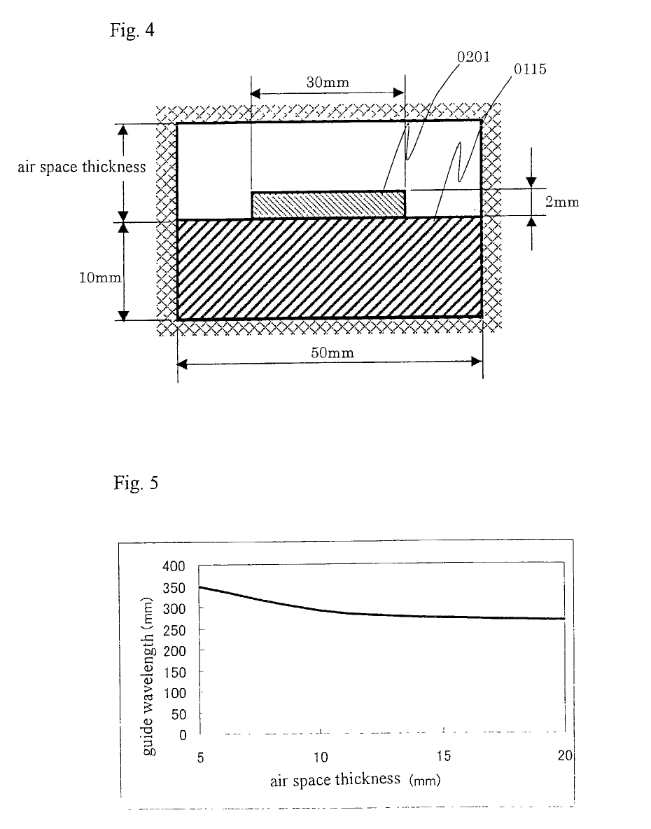

FIG. 4 illustrates a cross-sectional shape of the waveguide composed of the dielectric body 0115, the metal plate 0201 and the like. This structure is so-called a microstrip transmission line. A dielectric body 0115 is loaded within an outer conductor formed of a metal material having high conductivity and with a rectangular cross-section. The metal plate 0201 functions as an inner conductor. When the dielectric body 0115 is formed of alumina ceramic (relative dielectric constant: 9.8) and the members are formed to have sizes as illustrated in FIG. 4, the wavelength of the 450 MHz electromagnetic wave conducted through the present waveguide corresponding to the air space size shown in FIG. 4 is calculated as illustrated in FIG. 5. In the example, the relative dielectric constant of the air space portion is set to 1. For example, according to the calculation, when the air space thickness is 10 mm, the guide wavelength is 291 mm, and so the half-wavelength path difference is one-half the guide wavelength or 146 mm. Since the guide wavelength is varied when the air space thickness is changed, even if the true value of the guide wavelength differs from the calculated value, fine adjustment of the wavelength can be performed by varying the air space thickness. The reasons causing the guide wavelength to be different from the calculated value include calculation error and difference in relative dielectric constant. When the size of the waveguide is set as disclosed in FIG. 4 and the air space thickness is set to 10 mm, it is understood that the difference in lengths d1 and d2 shown in FIG. 2 should be set to 146 mm. Similarly, the phase difference can be adjusted freely by determining the length difference between d1 and d2.

A microstrip transmission line is utilized as a phase difference adjustment waveguide in the present embodiment, but the present invention is not limited to such example. The microstrip transmission line is advantageous in that it is relatively small and has a simple structure, but other waveguides such as coaxial lines can also be utilized.

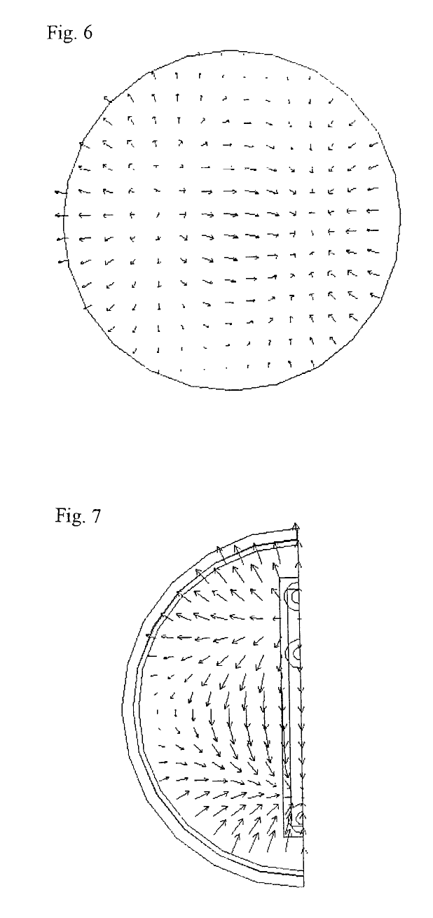

FIG. 6 illustrates in cross-section a TM11 mode electric field vector of a circular waveguide. The vectors are distributed as through electric fields are irradiated from two points within the cross-section of the circular waveguide. In order to excite an electromagnetic field having such distribution within the dielectric window 0105 shown in FIG. 1, two antennas for creating radial fields are prepared and excited in reverse phases, the antennas each being disposed near the portion where the TM11 mode electric field is generated radially. When the distance between the antennas is set to 300 mm, since the difference in length of d1 and d2 shown in FIG. 2 is 146 mm and the total length is 300 mm, it is understood that dl should preferably be set to 223 mm and d2 to 77 mm. Similarly, when the distance between both antennas and the guide wavelength are determined, the length of d1 and d2 in FIG. 2 is set accordingly, and the size of all the related parts are determined in a similar manner.

FIG. 7 illustrates the result of simulation of the electric field distribution at the interface between the shower plate and the plasma. The electric field distribution is computed assuming that uniform plasma exists within the processing chamber. In order to cut down the amount of calculation, a ½ model is used for calculation. It is understood from this result that a distribution similar to the TM11 mode of the circular waveguide is provided to the plasma.

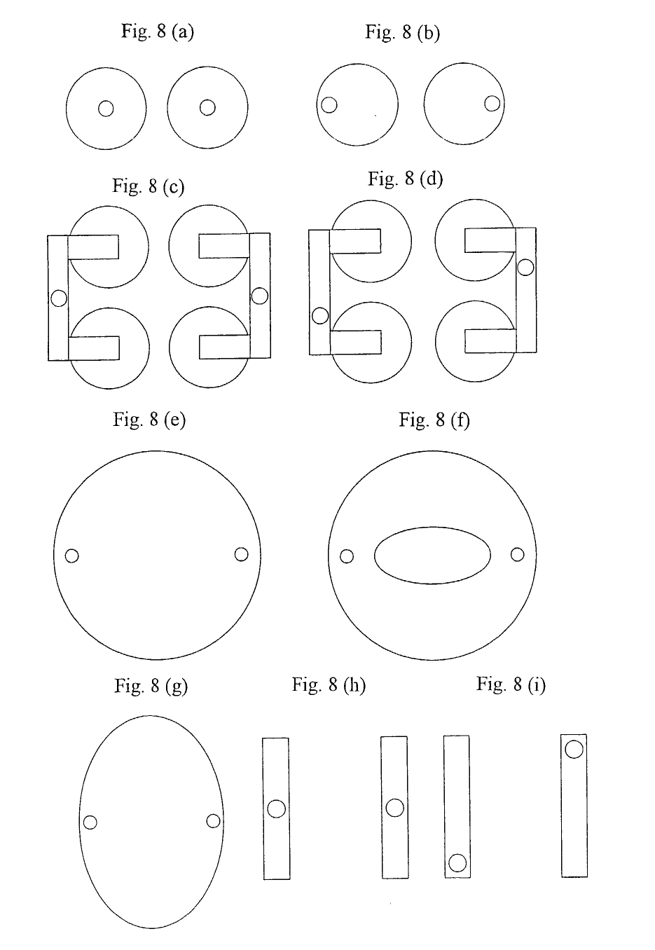

FIG. 8 shows various disk antennas that can be used instead of the antennas 0113 and 0114. FIG. 8(a) shows disk antennas utilized in the embodiment of FIG. 7. Power is supplied to the center of the disks. In the example of FIG. 8(b), power is supplied to decentered portions of the disk antennas, which is advantageous in that there is greater freedom in the location of the antennas and that the electromagnetic field distribution irradiated from the antennas is varied compared to the center-power-feed antennas. Moreover, as is shown in FIG. 8(c), the number of the disk antennas is not limited to two, but can be greater. The shape of the antenna is not limited to a circular disk, but can be oval, linear, arc and so on. In the example of FIG. 8(c), circuits branching two feeder lines into two, respectively, are provided so as to drive four antennas. In the example of FIG. 8(d), in addition to (c), there is difference in the distances from the branching point to the antennas, respectively, so as to adjust the phase for driving the antennas. By feeding power to four antennas with phases that differ by 90 degrees, respectively, the electromagnetic field irradiated from the four antennas create a rotating circular polarized wave. The electrons moving within the plasma having static magnetic field applied thereto receive Lorentz force perpendicular to the direction of the static magnetic field, and they perform a cyclotron motion winding around the line of magnetic force. By applying the circular polarized wave to the plasma so that rotates in the direction accelerating this cyclotron motion, the absorption property of the electromagnetic waves to the plasma is improved and a plasma density distribution having good axial symmetry is achieved. Moreover, the examples illustrated in (a) through (d) show examples for driving plural antennas, but also a single antenna can be used as illustrated in (e), (f) and (g). FIG. 8(e) is a circular disk antenna, (f) is a disk antenna with a hole in the center, and (g) is an oval shaped antenna. FIG. 8(f) adopts an oval hole and (g) adopts an oval shaped antenna in order to moderate the noaxisymmetricness of the TM11 mode. The above explanations were based on disk-shaped antennas, but the shape of the antenna is not limited to a disk, but can be linear as shown in (h) and (i), or flat plate shape, spiral etc.

In the present embodiment, waveguides having different lengths are utilized to provide a phase difference of 180 degrees to two feeding points. However, passive electric circuit elements such as condensers and coils can also be utilized to achieve the phase difference. FIG. 15 shows a circuit diagram. Antennas having impedance of Rₐ₁+jXₐ₁Ω and Rₐ₂+jXₐ₂Ω, respectively, are connected to a high frequency power source 1501 through passive electric circuit elements 1502 and 1503 having impedance of R₁+jX₁Ω and R₂+jX₂Ω, respectively. According to Ohm's law, the voltage Vₐ₁ and Vₐ₂ being generated at each antenna is:

Vₐ₁=(Rₐ₁+jXₐ₁)/(R₁+jX₁+Rₐ₁+jXₐ₁)V

Vₐ₂=(Rₐ₂+jXₐ₂)/(R₂+jX₂+Rₐ₂+jXₐ₂)V

Assuming that Xₐ₁=Xₐ₂=0 and R₁=R₂=0, the respective phase difference with the high frequency power source 1401 is:

−tan⁻¹(X₁/Rₐ₁)

−tan⁻¹(X₂/Rₐ₂)

Thus, by adjusting the passive electric circuit elements 1502 and 1503, it is possible to adjust the phase difference supplied to the antennas. Moreover, it is also possible to control the phase difference similarly by utilizing plural high frequency power sources having various controlled phases.

In the present embodiment, the frequency of the electromagnetic waves for generating plasma is 450 MHz. In general, the field distribution of electromagnetic waves within a closed space is increased in variety when the frequency is high, and in opposite the variation of distribution becomes limited when the frequency becomes low. In the case of a plasma processing device, when the frequency is high and the number of patterns of possible field distribution is high, the field distribution is caused to vary according to parameter fluctuation such as plasma density etc., which may lead to greatly varied plasma treatment characteristics. Thus, it becomes difficult to maintain the uniformity of the plasma treatment in a wide range of processing conditions. On the other hand, if the frequency is too low, the stability against parameter fluctuation is improved but the controllability of plasma becomes poor, making it difficult to control the plasma treatment characteristics. From such point of view, it is recognized that there is a certain preferable range regarding the frequency of the electromagnetic waves for generating plasma.

In order to perform a uniform plasma treatment, it is necessary to generate a substantially uniform plasma directly above the wafer to be treated. Electromagnetic waves tend to take patterns that vary substantially in the order of their wavelengths within the chamber, and this variation in pattern leads to uneven plasma distribution. Therefore, in order to obtain uniform plasma, it is preferable to either utilize electromagnetic waves having a wavelength equal to or greater than the size of the wafer to be treated or to utilize electromagnetic waves having a wavelength that is extremely short compared to the size of the wafer. In semiconductor fabrication such as VLSI (very-large-scale integrated circuit), wafers having diameters of 300 mm will become the trend in the near future. The frequency of an electromagnetic wave having a wavelength of 300 mm is 1 GHz. For example, plasma generated by a frequency of 2.45 GHz is relatively sensitive to process parameters, so it is considered that this corresponds to high frequency according to the above discussion on plasma controllability. Thus, considering both controllability and uniformity of plasma, a frequency of 1 GHz or smaller is thought to be the preferable frequency for generating plasma.

Further, from the viewpoint of phase control, if the wavelength is excessively long, all the location within the equipment is substantially driven by the same phase, so it becomes difficult to create a phase difference within the equipment. Thus, it is considered that the effect of phase control is realized when the frequency is equal to or greater than 10 MHz.

[Embodiment 2]

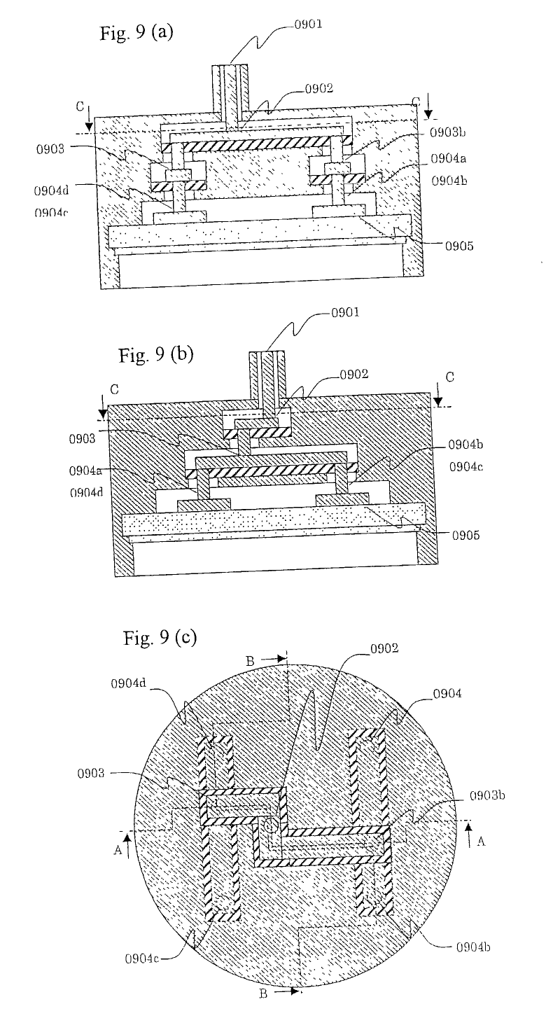

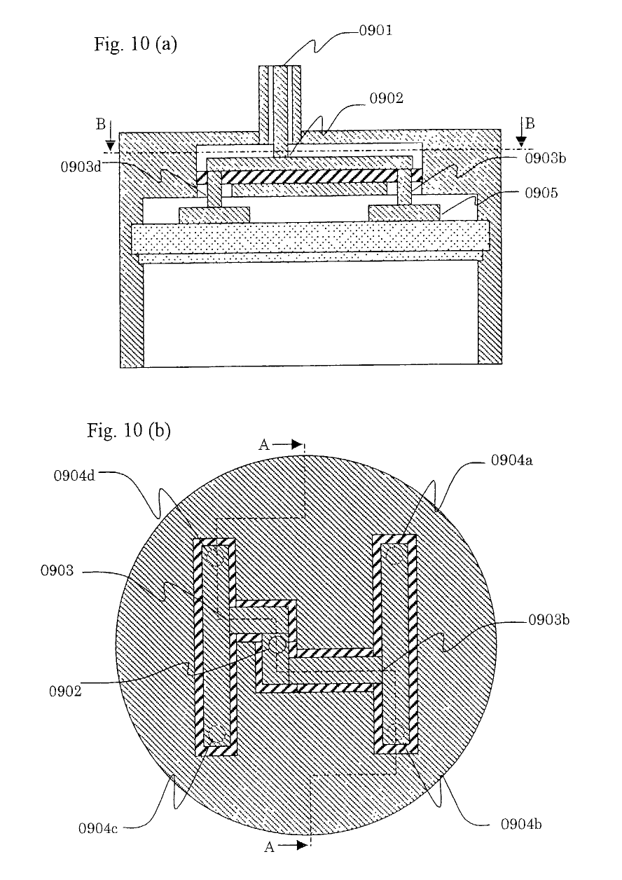

FIGS. 9 and 10 illustrate other preferred embodiments according to the present invention for feeding four antennas with phases that differ by 90 degrees, respectively. According to the example shown in FIG. 8(d), the antenna portion and the waveguide structure enabling phase control are not sufficiently separated electromagnetically, and thus according to plasma generation conditions it may not provide clear phase differences to the four antennas. The present embodiment is designed to solve such problem. Since the components excluding the antenna portion are the same as those in the embodiment of FIG. 1, detailed explanation of the common components are omitted. FIGS. 9(a), (b) and (c) are all cross-sectional diagrams of the equipment, wherein FIG. 9(a) is an AA cross-section of 9(c), 9(b) is a BB cross-section of 9(c), and 9(c) is a CC cross-section of 9(a) and 9(b). The portions other than the phase adjustment circuit are the same as the embodiment of FIG. 1, so detailed explanations thereof are omitted. The 450 MHz electromagnetic waves provided through an electromagnetic wave intake port 0901 are branched at a first branch 0902 so that electromagnetic waves are supplied to branches 0903a and 0903b having relative phases of +90 degrees and −90 degrees, respectively. Branches 0903a and 0903b further branch the electromagnetic waves to have relative phases of +45 degrees and −45 degrees, respectively, before transmitting the electromagnetic waves to the feeding units 0904a, 0904b, 0904c and 0904d, respectively. Finally, the neighboring feeding units are driven by electromagnetic waves having 90-degree phase differences, respectively. Antenna 0905 is connected to each feeding unit, each antenna radiating electromagnetic waves having 90-degree phase differences into the plasma processing chamber. Thus, circular polarized waves are generated so as to improve the evenness of plasma distribution. Moreover, by combining this structure with static magnetic field, the direction of rotation of the electric field can be set to accelerate the cyclotron motion of the electrons, thereby improving the efficiency of absorption of electromagnetic waves to plasma.

Though according to the present embodiment the antenna 0905 is divided into four parts, but it can also be formed as a single member.

According to the embodiment illustrated in FIG. 9, the branches 0902, 0903a and 0903b have the same structures, the branch on the first level and the branches on the second level constituting a two-layer structure. However, the branches 0903a and 0903b can be formed as so-called T-type branches, constituting a one-layer structure. The simplified equipment adopting such one-layer structure is illustrated in cross-section in FIG. 10. FIG. 10(a) is an AA cross-section of FIG. 10(b), and FIG. 10(b) is a BB cross-section of FIG. 10(a). The one-layer structure effectively minimizes the size of the equipment and cuts down the number of required components.

[Embodiment 3]

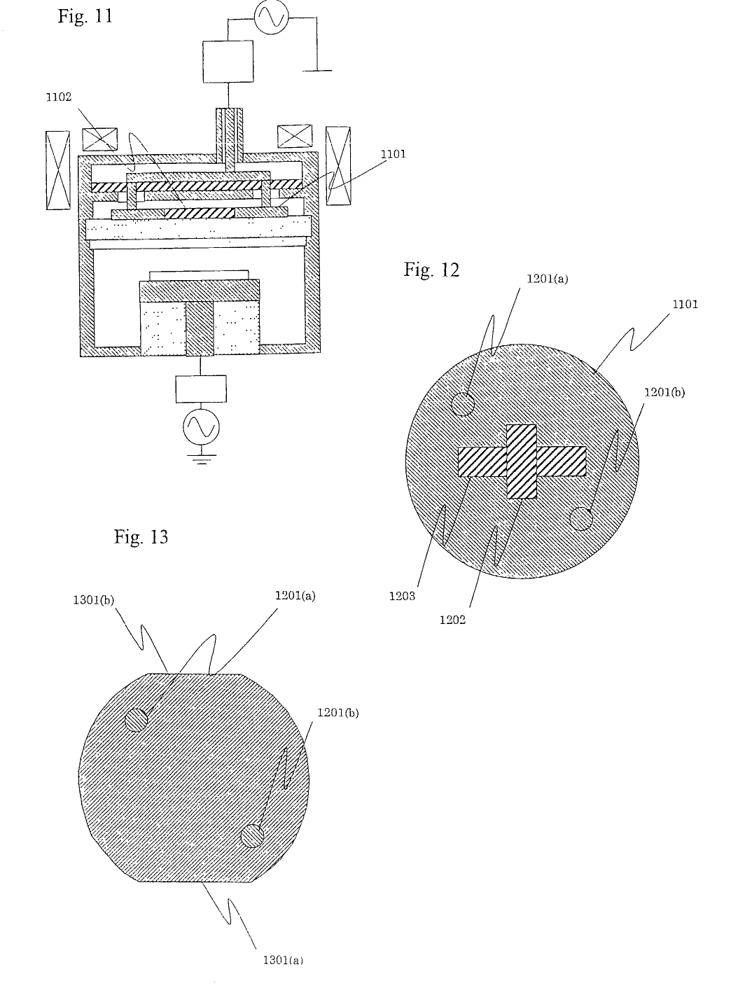

FIG. 11 illustrates another embodiment of the present invention that realizes the rotating electric field. According to embodiment 2, phase difference is provided by utilizing waveguides having different lengths, but in the embodiment of FIG. 11, phase difference is provided by utilizing an antenna having perturbation provided to the resonance condition.

Since only the antenna portion differs between the present embodiment and the embodiment of FIG. 1, explanations on the other common portions are omitted. An antenna plate 1101 having power fed from two feeding points that are driven with a phase difference of 180 degrees is prepared, and on the-antenna plate 1101 is provided a slot antenna 1102 formed by mounting a dielectric body such as alumina ceramic on the antenna plate 1101. FIG. 12 shows in detail the antenna plate 1101 and the slot antenna 1102.

Near the center of the antenna plate 1101 are two slots 1202 and 1203 which are loaded with alumina ceramic. The slot 1203 is relatively long as opposed to the resonance length, and slot 1202 is relatively short. Electromagnetic waves excited with a mutual phase difference of 180 degrees are supplied to the feeding points 1201(a) and 1201(b), respectively. Slots 1202 and 1203 are orthogonal to each other. Further, feeding points 1201(a), 1201(b) and slots 1202, 1203 are relatively positioned so that the longitudinal axes of slots 1202 and 1203 cross the line connecting feeding points 1201(a) and 1201(b) at an angle of 45 degrees, respectively.

Slots 1202 and 1203 each function as slot antennas. The slot antennas resonate when their lengths correspond to half-length of the electromagnetic wave or to the integral multiplication thereof, effectively radiating electromagnetic waves. By adjusting the relative dielectric constant of the dielectric body loaded inside the slots, the resonating slot length can be controlled. In the present embodiment, alumina ceramic is utilized to reduce the size of the slot antennas. When the slot length is either somewhat longer than or shorter than the resonance length, the phase of the electromagnetic waves radiated through the slots is displaced. From the two slots disposed orthogonal to each other are radiated electric fields that are also orthogonally oriented, and by providing phase difference to these electromagnetic waves, rotating components can be generated. When radiating electromagnetic waves having the same power through the two orthogonally positioned slots for radiating the electric fields, a phase difference of 90 degrees is provided to realize electromagnetic waves that rotate efficiently. According to the structure mentioned above, electromagnetic waves having rotating electric field components can be radiated, thereby realizing similar effects as the second embodiment.

One pair of orthogonally positioned slot antennas are utilized in the present embodiment, but similar effects can be realized by providing a greater number of slot antennas. The relative angular position of the feeding points and the slot antennas are not limited to those explained in the present embodiment, but can be adjusted according to the power radiated through each slot antenna or the phase difference between the feeding points. According further to the present embodiment, a method is adopted where a rotating electromagnetic field is created by combining two types of electromagnetic waves having a 90-degree phase difference and thus having a 90-degree electric field angle difference. However, a rotating electromagnetic field can also be created by combining three types of electromagnetic waves each having a 60-degree phase difference, thus creating electric fields with angles that differ by 60 degrees.

FIG. 13 illustrates another example of an antenna that can be used in replacement of the antenna plate 1101. Notches 1301(a) and 1301(b) are provided to a substantially circular conductor plate. According to this structure, the resonance point in the direction having the notches can be displaced from that in the direction orthogonal thereto, thus achieving the same effects as those of the slot antennas of FIG. 12.

[Embodiment 4]

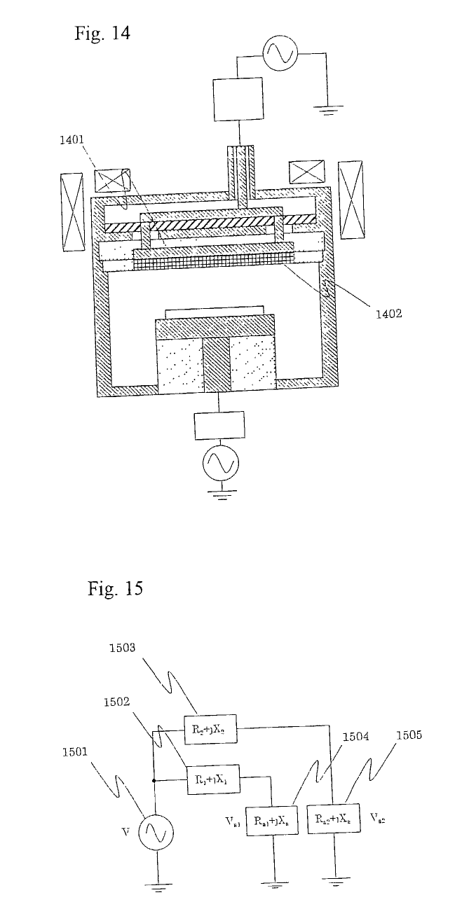

Though according to embodiments 1, 2 and 3 the antennas are disposed on the atmospheric side of the dielectric window, the antennas an also be located on the plasma chamber side thereof. The device structure becomes more complicated, but since electromagnetic waves can be provided directly to the plasma without passing through the dielectric window etc., this structure is advantageous in that the controllability of the plasma is improved and the plasma density can easily be increased. This embodiment only differs from the embodiment illustrated in FIG. 11 in the structure of and around the antenna, so the explanations on the other common areas are omitted. According to the embodiment illustrated in FIG. 14, a shower plate 1402 formed of a material such as silicon that has no adverse effect on plasma treatment is positioned to substantially come into contact with an antenna plate 1401. The antenna plate 1301 can adopt any structure illustrated in FIG. 8, FIG. 12 or FIG. 13. Treatment gas supplied from a gas supply system not shown is provided to the plasma processing chamber through the shower plate 1402. The use of antenna plate 1401 enables electric field components which are perpendicular to the static magnetic field to be created near the center axis, advantageously improving the density near the center area and advancing the evenness of plasma density. Moreover, the generation of a rotating electric field further advances the plasma uniformity. Moreover, a bias power source of 13.56 MHz, for example, can be connected to the shower plate 1402 to provide bias potential thereto. According to such example, the excessive active species generated within the plasma can be reacted on the shower plate surface and the quantity of active species can thereby be controlled effectively.

The embodiment of FIG. 14 creates a rotating field using a slot antenna and the like, but the technique utilizing the route length difference as illustrated in embodiments 1, 2 and 3 can similarly be used.

[Embodiment 5]

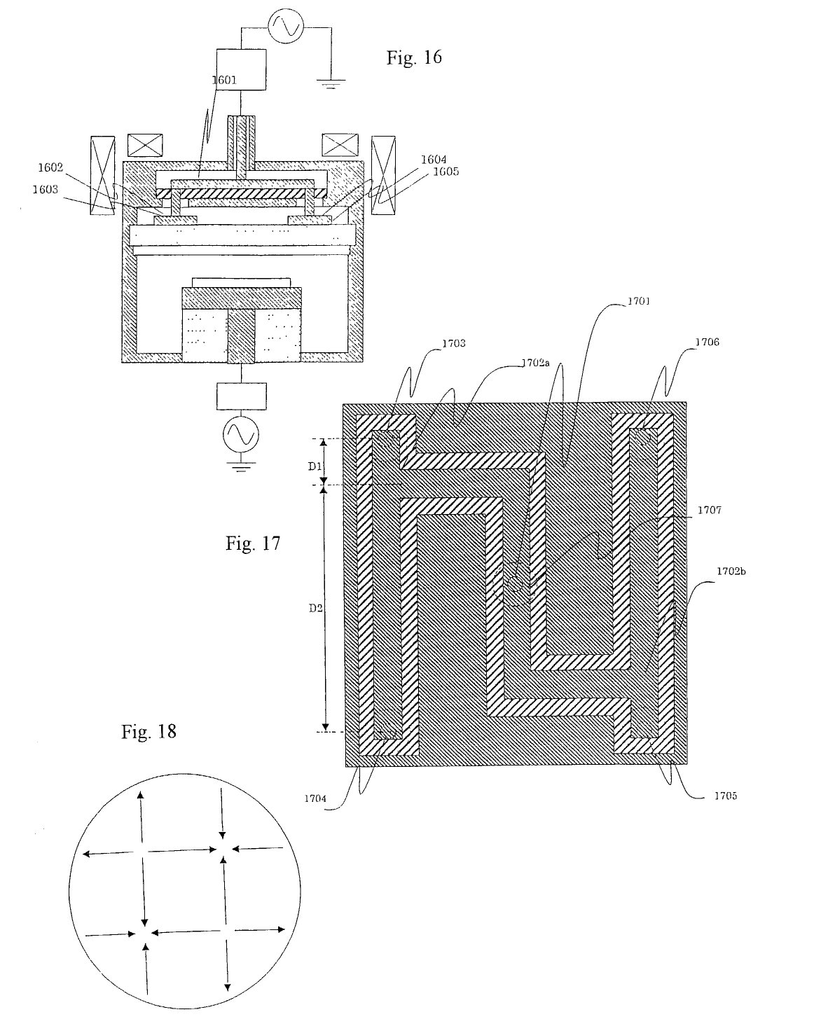

FIGS. 16 through 19 are referred to in explaining another embodiment of the present invention. FIG. 16 illustrates an etching device utilizing the present invention. The branch circuit portion of UHF, the structure of the antennas connected to the branch circuit and the mode of the UHF provided to the chamber of the present embodiment differ from the first embodiment illustrated in FIG. 1, but other components are the same, so detailed explanations on the common portions are omitted. The UHF power of 450 MHz is transmitted via an automatic matching unit and coaxial line to a phase adjustment circuit 1601. As is shown in FIG. 17, the phase adjustment circuit 1601 outputs the electromagnetic waves input through the coaxial line to four output ports. Disk antennas 1602, 1603, 1604 and 1605 are connected to the four output ports, respectively, through which the electromagnetic waves are irradiated into the processing chamber via a dielectric window and a shower plate. The irradiated electromagnetic waves generate a plasma within the processing chamber, which is utilized to perform etching to the wafer disposed within the processing chamber.

The detailed structure around phase adjustment circuit 1601 is illustrated in FIG. 17. FIG. 17 illustrates the phase adjustment circuit 1601 oriented orthogonally from the direction of FIG. 16. The phase adjustment circuit is composed of a waveguide so-called a microstrip line as illustrated mainly in FIG. 4, and a branch circuit utilizing the waveguide, functioning to branch the electromagnetic waves input from a single input port to a total of four output ports with determined phase differences.

The coaxial line 1701 disposed along the center axis of the device is connected to a first branch 1707 composed of a microstrip line, thereby converting the path to a microstrip line and branching the electromagnetic waves into two directions. The branched microstrip lines are each further branched into two directions at the second branch portions 1702a, 1702b. Finally, the electromagnetic waves input through the coaxial line 1701 are branched to four output ports 1703, 1704, 1705 and 1706. The distances D1 and D2 from the branched portion 1702a to output ports 1703 and 1704 are set so that the absolute value of the difference |D2−D1| is λ/2 in relation to the wavelength λ of the electromagnetic waves within the microstrip transmission line. Therefore, the phase difference of electromagnetic waves output from the output port 1703 and output port 1704 is 180 degrees. Output ports 1705 and 1706 have a similar structure, in which the phase difference of output electromagnetic waves is also 180 degrees. Finally, electromagnetic waves having the same phase are output through output ports 1703 and 1705, and electromagnetic waves having a 180-degree phase difference therefrom are output through ports 1704 and 1706. Moreover, the output ports 1703, 1704, 1705 and 1706 are disposed so that the center points of each port define each apex of a square. Disk antennas 1602, 1603, 1604 and 1605 are connected to output ports 1703, 1704, 1705 and 1706, respectively.

Generally, if there is a mismatch portion of impedance existing within the waveguide in relation to the electromagnetic waves conducted therethrough, reflected waves are generated at that portion. Within the phase adjustment circuit illustrated in FIG. 17, reflected waves of UHF power are generated at the branch portions etc. When reflected waves are generated, the supplied power cannot be transmitted efficiently to the plasma processing chamber. Therefore, in order to prevent reflection from occurring at the branch portion etc., an impedance matching unit can be provided within the phase adjustment circuit. For example, it is possible to adopt structures with varied width or height of the inner conductors of the microstrip transmission line, or structures with varied height or width of the outer conductors.

The microstrip transmission line has the same structure as the waveguide utilized in embodiment 1, so detailed explanation thereof is omitted. Similar to embodiment 1, according to the present embodiment the phase adjustment waveguide is not limited to a microstrip transmission line, but can be any other waveguide such as a coaxial line etc. Even further, instead of utilizing the waveguide with route length differences, a phase adjustment circuit utilizing circuit elements such as inductors or capacitors can be adopted.

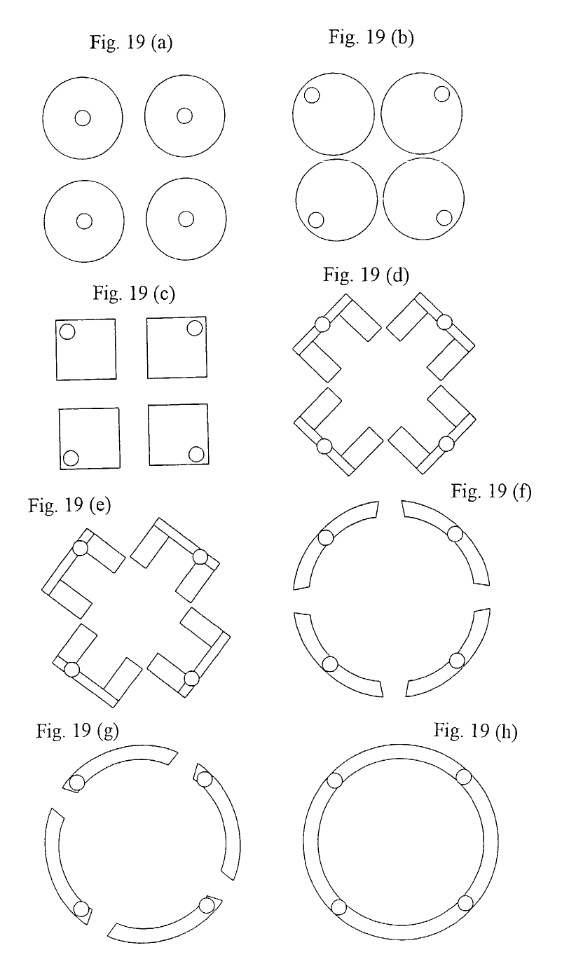

FIG. 18 illustrates the frame format of the electric field vector of the TM21 mode circular waveguide. According to the distribution, the electric fields are substantially generated radially from two points within the circular waveguide and drawn into other two points. By utilizing the afore-mentioned phase adjustment circuit 1601 to provide electromagnetic waves having a phase difference of 180 degrees to the adjacent two points, the TM21 mode illustrated in FIG. 18 can be realized.

According to the above embodiment, disk antennas 1602, 1603, 1604 and 1605 are connected to the four output ports 1703, 1704, 1705 and 1706 of the phase adjustment circuit 1601, respectively, so as to irradiate UHF power. However, the shape of the antennas connected to the output port is not limited to a disk, but can be in other forms. Possible antenna shapes to be connected to the output ports are illustrated in FIG. 19. FIG. 19(a) illustrates the case where the inner conductor of each output port is connected to supply power to the center of four disk antennas, and (b) illustrates an example where the power feed points are decentered from the center of the disk antennas. According to the antennas illustrated in (b), the distance between the disk antennas can be approximated without changing the position of the output ports, which increases the freedom of the location of the antennas. FIG. 19(c) illustrates an example where the disk antennas of (b) are replaced with rectangular antennas. In order to approximate the center position of the antennas above a certain level, the disk antennas must be reduced in diameter size. If the projection area of the antennas to the UHF introduction window is small, the ignitionability of plasma is deteriorated, but according to the rectangular antenna shape the projection area can be secured to a certain level, so the use of such antennas can prevent the deterioration of ignitionability. FIG. 19(d) illustrates an example where two rod-like antennas are connected to the inner conductor of each output port, and (e) illustrates an example where difference is provided to the path leading to the two rod-like antennas. According to (d), the UHF power is supplied from a total of eight excitation points, which effectively smoothes the plasma distribution. Moreover, according to (e), a difference is provided to the path leading to the two rod-like antennas connected to each output port, and by adjusting the route difference so that a phase difference of approximately 90 degrees is achieved, the electric field distribution can be rotated. Since the electric field distribution is flattened by rotation, the plasma distribution is further uniformed advantageously. FIGS. 19(f) and (g) illustrate examples where arc-shaped antennas are connected to the inner conductor of the output ports. FIG. 19(f) shows the case where the power is fed to the center of each arc, and (g) shows the case where the power is fed to the end of each arc. By utilizing arc-shaped antennas, the UHF is conducted along the arc and absorbed in the plasma, effectively smoothing the plasma distribution. Moreover, FIG. 19(h) illustrates the case where the arc antennas of (f) and (g) are connected to form a ring antenna. The utilization of a ring antenna instead of arc antennas increases the area of the antenna interacting with plasma or the area of projection to the UHF introduction window, thus improving for example the ignitionability of the plasma.

Generally, in a phase adjustment circuit utilizing the path difference as illustrated in FIG. 17, the generation of reflected waves at the joint surface between the load and the output port causes standing waves to occur within the phase adjustment circuit, which may make it impossible to supply electromagnetic waves to the load with desired phase differences. Therefore, in many cases an impedance-matching circuit is provided between the load and the output ports to realize impedance match so as to prevent the occurrence of reflected waves. However, in case the structure illustrated in FIG. 16 is used to drive a TM21 mode into the dielectric window, the dielectric window itself has a property to take on the electromagnetic field distribution of this mode, so it is not always necessary to provide an impedance-matching circuit to prevent reflected waves. Similarly, there is no need to set the path difference D1−D2 of the phase adjustment circuit 0104 to precisely correspond to half wavelength, because even if there is some deviation in the path difference, TM21 mode can still be excited into the dielectric window. As explained, the dielectric window itself can be utilized for selecting the modes.

According to the present invention, the conventional problem of electric fields being concentrated at the center area can be prevented, and a uniform plasma processing is achieved easily.

What is claimed is:

1. A plasma processing device that utilizes electromagnetic waves to generate plasma, comprising:
a generation apparatus for creating plasma-generating electromagnetic waves;
a plasma processing chamber;
an electromagnetic wave radiation apparatus for introducing electromagnetic waves into the plasma processing chamber;
a dielectric window for introducing electromagnetic waves into the plasma processing chamber;
a substrate electrode for mounting a wafer within the plasma processing chamber; and
a vacuum pumping system and a gas introduction system for controlling the plasma processing chamber to a predetermined pressure and gas atmosphere; wherein
the plasma-generating electromagnetic waves are introduced to the plasma processing chamber by utilizing one or more antennas having plural power feed points that are excited with a fixed phase difference.

2. A plasma processing device that utilizes electromagnetic waves to generate plasma, comprising:
a generation apparatus for creating plasma-generating electromagnetic waves;
a plasma processing chamber;
an electromagnetic wave radiation apparatus for introducing electromagnetic waves into the plasma processing chamber;
a dielectric window for introducing electromagnetic waves into the plasma processing chamber;
a substrate electrode for mounting a wafer within the plasma processing chamber;
an apparatus for applying a static magnetic field substantially perpendicular to the wafer; and
a vacuum pumping system and a gas introduction system for controlling the plasma processing chamber to a predetermined pressure and gas atmosphere; wherein
the plasma-generating electromagnetic waves are introduced to the plasma processing chamber by utilizing one or more antennas having plural power feed points that are excited with a fixed phase difference.

3. A plasma processing device according to claim 1 or claim 2, wherein said one or more antennas excited through plural power feed points are disposed substantially in contact with the dielectric window for introducing electromagnetic waves into the plasma processing chamber.

4. A plasma processing device according to claim 1 or claim 2, wherein said power feed points excited with a fixed phase difference are set to have a phase difference of 180 degrees.

5. A plasma processing device according to claim 1 or claim 2, wherein the device comprises N power feed points (N being an integral number equal to or greater than three) that are excited with fixed phase differences, the phase difference between adjacent power feed points being 360/N degrees.

6. A plasma processing device according to claim 1 or claim 2, wherein said phase difference is created using a waveguide having different lengths to the power feed points.

7. A plasma processing device according to claim 1 or claim 2, wherein said phase difference is created using a passive electric circuit element such as a condenser or a coil.

8. A plasma processing device according to claim 1 or claim 2, wherein said phase difference is created using plural phase-controlled high frequency power sources.

9. A plasma processing device according to claim 1 or claim 2, wherein said antennas are directly exposed within said plasma processing chamber.

10. A plasma processing device according to claim 1 or claim 2, wherein the frequency of said electromagnetic waves used for generating plasma is within the range equal to or smaller than 1 GHz and equal to or greater than 10 MHz.

11. A plasma processing device according to claim 1 or claim 2, wherein said electromagnetic waves radiated from the antennas become circular polarized waves.

12. A plasma processing device according to claim 2, wherein according to said apparatus for applying a static magnetic field, the electric field rotates in the right direction in relation to the direction of said static magnetic field.

13. A plasma processing device that utilizes electromagnetic waves to generate plasma, comprising:
a generation apparatus for creating the electromagnetic waves for generating plasma;
a plasma processing chamber;
an electromagnetic wave radiation apparatus for introducing electromagnetic waves into the plasma processing chamber;
a dielectric window for introducing electromagnetic waves into the plasma processing chamber;
a substrate electrode for mounting a wafer within the plasma processing chamber; and
a vacuum pumping system and a gas introduction system for controlling the plasma processing chamber to a predetermined pressure and gas atmosphere; wherein
said electromagnetic waves for generating plasma are output through output ports, said output ports being disposed in a substantially square configuration;
the electromagnetic waves output through adjacent output ports have phase differences; and
antennas connected to said output ports are used to introduce said plasma-generating electromagnetic waves to the plasma processing chamber.

14. A plasma processing device according to claim 13, further comprising four output ports, the phase difference of electromagnetic waves being set to substantially 180 degrees.

15. A plasma processing method that generates plasma using electromagnetic waves and processes a wafer by the generated plasma, said processing method comprising the steps of:
outputting plasma-generating electromagnetic waves from four output ports disposed substantially in square configuration;
setting the phase difference between electromagnetic waves output from adjacent output ports to substantially 180 degrees;
introducing said plasma-generating electromagnetic waves into a plasma processing chamber using antennas connected to said output ports; and
processing the wafer.

16. A plasma processing method that generates plasma using electromagnetic waves, said method comprising the steps of:
generating plasma-generating electromagnetic waves;
introducing the generated electromagnetic waves into the plasma processing chamber;
mounting a wafer to be processed in the plasma processing chamber;
treating the mounted wafer by the generated plasma;
controlling the plasma processing chamber to a predetermined pressure and gas atmosphere; and
introducing the plasma-generating electromagnetic waves into the plasma processing chamber using antennas having plural power feed points that are excited with a fixed phase difference.
